(19) United States
(12) Patent Application Publication
(10) Pub. No.: US 2026/0047476 A1
(43) Pub. Date: Feb. 12, 2026

(54) CHIP STRUCTURE HAVING INTERCONNECT AND MANUFACTURING METHOD THEREOF

(71) Applicant: DB HiTek Co., Ltd., Bucheon-si (KR)

(72) Inventor: Jong Won SUN, Icheon-si (KR)

(21) Appl. No.: 18/916,939

(22) Filed: Oct. 16, 2024

(30) Foreign Application Priority Data
Aug. 6, 2024 (KR) 10-2024-0104305

(51) Int. Cl. H01L 23/31; H01L 21/321; H01L 21/56; H01L 21/768; H01L 23/00; H01L 23/522; H01L 23/528; H01L 23/532

(52) U.S. Cl. CPC H01L 23/3171; H01L 21/3212; H01L 21/56; H01L 21/76802; H01L 21/76843; H01L 21/76883; H01L 23/5226; H01L 23/528; H01L 23/53266; H01L 24/05; H01L 24/11; H01L 24/13; H01L 2224/05073; H01L 2224/05184; H01L 2224/05582; H01L 2224/05647; H01L 2224/05666; H01L 2224/05684; H01L 2224/11001; H01L 2224/13147; H01L 2224/13582; H01L 2224/13644; H01L 2224/13655; H01L 2924/3512

(57) ABSTRACT

A chip structure having an interconnect and a manufacturing method thereof include a buffer layer formed between an upper metal structure and a passivation layer under the upper metal structure so as to prevent fractures, such as cracks, from occurring in the passivation layer due to difference of stress between the upper metal structure and the passivation layer.

### CROSS REFERENCE TO RELATED APPLICATION

The present application claims priority to Korean Patent Application No. 10-2024-0104305, filed Aug. 6, 2024, the entire contents of which are incorporated herein for all purposes by this reference.

### BACKGROUND OF THE INVENTION

### Field of the Invention

The present disclosure relates generally to a chip structure having an interconnect and a manufacturing method thereof. More particularly, the present disclosure relates to a chip structure having an interconnect, in which a buffer layer is formed between an upper metal structure and a passivation layer under the upper metal structure so as to prevent fractures, such as cracks, from occurring in the passivation layer due to difference of stress between the upper metal structure and the passivation layer, and a manufacturing method thereof.

### Description of the Related Art

In general, redistribution layer (RDL) processes are processes of forming a new pad by re-forming a metal layer for a redistribution layer on a pad formed on a substrate. Products to which a copper RDL process among these processes is applied perform a process of forming a copper metal layer on a passivation layer. In this case, there is a possibility that cracks may occur in the passivation layer due to stress applied or transmitted to the passivation layer on a lower side of the copper metal layer through the copper metal layer having a relatively large vertical thickness.

In order to solve the above-mentioned problems, the inventor of the present disclosure proposes a novel chip structure having an interconnect and a manufacturing method thereof, and details thereof will be described later.

### DOCUMENT OF RELATED ART

(Patent Document) U.S. Pat. No. 6,908,848 ‘METHOD FOR FORMING AN ELECTRICAL INTERCONNECTION PROVIDING IMPROVED SURFACE MORPHOLOGY OF TUNGSTEN’

### SUMMARY OF THE INVENTION

Accordingly, the present disclosure has been made keeping in mind the above problems occurring in the related art, and the present disclosure is intended to propose a chip structure having an interconnect, in which a buffer layer is formed on a gap fill layer so as to prevent the possibility of cracks occurring in a passivation layer due to stress applied thereto when forming an upper metal structure, and a manufacturing method thereof.

In addition, the present disclosure is intended to propose a chip structure having an interconnect, in which the buffer layer on the gap fill layer is formed of a material identical to a material of the gap fill layer so as to eliminate the need for an additional material for forming the buffer layer, and a manufacturing method thereof.

In addition, the present disclosure is intended to propose chip structure having an interconnect, in which the buffer layer is formed as a single W (tungsten) layer or as a layer in which one or more layers of TiW, Ti, and TiN are stacked on the W layer so as to prevent cracks from occurring in the passivation layer, and a manufacturing method thereof.

In addition, the present disclosure is intended to propose a chip structure having an interconnect, in which through a CMP process when forming the gap fill layer, a material layer constituting the gap fill layer on the passivation layer is not completely removed, but remains to have a predetermined thickness, and thus the buffer layer is naturally formed in the formation process of the gap fill layer so as to eliminate the need for a separate process for forming the buffer layer, and a manufacturing method thereof.

The present disclosure may be implemented through embodiments with the following configuration to achieve the purposes described above.

According to an embodiment of the present disclosure, a chip structure having an interconnect according to the present disclosure includes: a substrate; an insulating film on the substrate; multiple layers of metal wirings within the insulating film; and a contact plug for electrically connecting each of the metal wirings to each other; a metal pad on the insulating film or in an upper portion of the insulating film; a passivation layer located on the insulating film and having one or more via holes; a metal material layer configured to fill each of the via holes; a buffer layer on the passivation layer and the metal material layer; a UBM layer on the buffer layer; and an upper metal structure on the UBM layer.

According to another embodiment of the present disclosure, in the chip structure having an interconnect according to the present disclosure, the metal material layer may include: a barrier layer along an inner wall of the via hole; and a gap fill layer inside the via hole and on the barrier layer.

According to another embodiment of the present disclosure, in the chip structure having an interconnect according to the present disclosure, the barrier layer may be a Ti layer and/or a TiN layer.

According to another embodiment of the present disclosure, in the chip structure having an interconnect according to the present disclosure, the gap fill layer may be a W layer.

According to another embodiment of the present disclosure, in the chip structure having an interconnect according to the present disclosure, the buffer layer, which is a protective layer, may be made of a metal material identical to a metal material of the gap fill layer.

According to another embodiment of the present disclosure, in the chip structure having an interconnect according to the present disclosure, the buffer layer may be a W layer.

According to another embodiment of the present disclosure, in the chip structure having an interconnect according to the present disclosure, the buffer layer may have a structure in which a W layer and at least one layer of a Ti layer, a TiN layer, and a TiW layer on the W layer are stacked.

According to another embodiment of the present disclosure, in the chip structure having an interconnect according to the present disclosure, the UBM layer may include: a first layer on the protective layer; and a second layer on the first layer.

According to another embodiment of the present disclosure, in the chip structure having an interconnect according to the present disclosure, the second layer may be made of a metal material identical to a metal material of a lower portion of the upper metal structure.

According to another embodiment of the present disclosure, in the chip structure having an interconnect according to the present disclosure, the second layer may be a Cu metal layer.

According to another embodiment of the present disclosure, in the chip structure having an interconnect according to the present disclosure, the upper metal structure may include: a first metal layer on a lowest side thereof; a second metal layer on the first metal layer; and a third metal layer on the second metal layer, wherein the first metal layer, the second metal layer, and the third metal layer may be made of metal materials different from each other.

According to another embodiment of the present disclosure, in the chip structure having an interconnect according to the present disclosure, the first metal layer may have a larger vertical thickness than each of the second metal layer and the third metal layer.

According to another embodiment of the present disclosure, a chip structure having an interconnect according to the present disclosure includes: a substrate; an insulating film on the substrate; a metal pad on the insulating film or in an upper portion of the insulating film; a passivation layer having a via hole and located on the insulating film; a barrier layer extending along an inner wall of the via hole; a gap fill layer inside the via hole and on the barrier layer; a buffer layer on the passivation layer and the gap fill layer; a UBM layer, which is a multilayer film structure, on the buffer layer; and an upper metal structure on the UBM layer, wherein the gap fill layer is made of a metal material identical to a metal material of the buffer layer.

According to another embodiment of the present disclosure, in the chip structure having an interconnect according to the present disclosure, the UBM layer may include: a first layer; and a second layer on the first layer, wherein the second layer may be made of a metal material identical to a metal material of a lower portion of the upper metal structure in contact with an upper surface of the second layer.

According to another embodiment of the present disclosure, in the chip structure having an interconnect according to the present disclosure, the buffer layer may be formed together with the gap fill layer during a CMP process to complete the gap fill layer.

According to another embodiment of the present disclosure, a manufacturing method of a chip structure having an interconnect according to the present disclosure includes: forming a passivation layer on an insulating film in which a metal wiring layer is formed; forming one or more via holes inside the passivation layer; forming a barrier layer along an inner wall of each of the via holes; forming a gap fill layer on the barrier layer within the via hole; forming a buffer layer on the gap fill layer; forming a UBM layer on the buffer layer; and forming an upper metal structure on the UBM layer.

According to another embodiment of the present disclosure, in the manufacturing method of the chip structure having an interconnect according to the present disclosure, the barrier layer and the gap fill layer may be formed by forming the barrier layer along the inner wall of the via hole, forming the gap fill layer on the barrier layer, and then removing at least a portion of the gap fill layer remaining outside the via hole through a CMP process.

According to another embodiment of the present disclosure, in the manufacturing method of the chip structure having an interconnect according to the present disclosure, the buffer layer may be formed by removing a predetermined thickness of the gap fill layer remaining outside the via hole through the CMP process.

According to another embodiment of the present disclosure, in the manufacturing method of the chip structure having an interconnect according to the present disclosure, the forming of the UBM layer may include: forming a first layer comprising a Ti layer or a TiW layer; and forming a second layer, which is a Cu layer, on the first layer.

According to another embodiment of the present disclosure, in the manufacturing method of the chip structure having an interconnect according to the present disclosure, the forming of the upper metal structure may include: forming a photoresist film located on the UBM layer and having an opening; and forming a plurality of metal layers sequentially within the opening.

The present disclosure has the following effects due to the configuration described above.

According to the present disclosure, the buffer layer is formed on the gap fill layer, thereby preventing the possibility of cracks occurring in the passivation layer due to stress applied thereto when forming the upper metal structure.

In addition, according to the present disclosure, the buffer layer on the gap fill layer is formed of a material identical to a material of the gap fill layer, thereby eliminating the need for an additional material for forming the buffer layer.

In addition, according to the present disclosure, the buffer layer is formed as a single W (tungsten) layer or as a layer in which one or more layers of TiW, Ti, and TiN are stacked on a W layer, thereby preventing cracks from occurring in the passivation layer.

In addition, according to the present disclosure, through the CMP process when forming the gap fill layer, a material layer constituting the gap fill layer on the passivation layer is not completely removed, but remains to have a predetermined thickness, and thus the buffer layer is naturally formed in the formation process of the gap fill layer, thereby eliminating the need for a separate process for forming the buffer layer.

Meanwhile, it should be added that even if effects are not explicitly mentioned here, the effects described in the following specifications and potential effects thereof expected by the technical features of the present disclosure are treated as if they were described in the specifications of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a chip structure having an interconnect according to an embodiment of the present disclosure; and

FIGS. 2 to 11 are cross-sectional views illustrating a manufacturing method of the chip structure having an interconnect according to an embodiment of the present disclosure.

### DETAILED DESCRIPTION OF THE INVENTION

Hereinafter, embodiments of the present disclosure will be described in more detail with reference to the attached drawings. The embodiments of the present disclosure may be modified in various forms, and the scope of the present disclosure should not be construed as limited to the embodiments below and should be interpreted on the basis of the matters stated in the claims. In addition, these embodiments are only provided as a reference to more completely explain the present disclosure to those with average knowledge in the art.

Hereinafter, when a first component (or layer) is described as being placed on a second component (or layer), it should be noted that the first component may be placed directly on the second component, or there may be a third component(s) or layer(s) located between the corresponding components. Additionally, when the first component is expressed as being placed directly on or above the second component, no other component(s) are located between the corresponding components. In addition, being located on the ‘upper part’, ‘lower part’, ‘upper side’, ‘lower side’ or ‘one side’ or ‘side surface’ of the first component means a relative positional relationship.

Additionally, terms such as first and second, etc. may be used to describe various items such as various elements, regions, and/or parts, but the items are not limited by these terms.

In addition, it should be noted that in a case in which a specific embodiment can be implemented differently, a specific process sequence may be different from a process sequence to be described below. For example, two processes described sequentially may be performed substantially at the same time or may be performed in the opposite order.

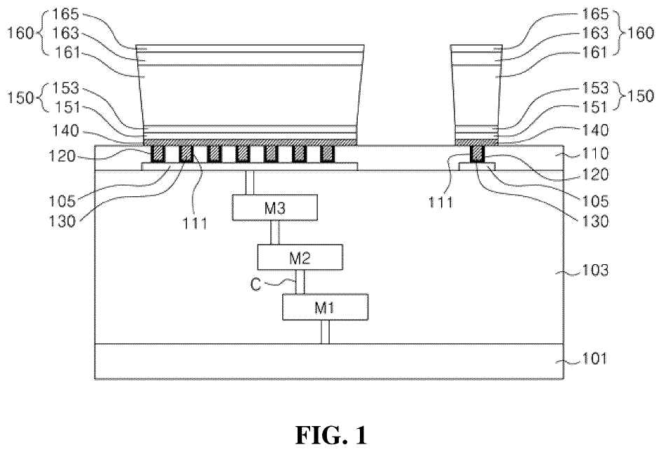

FIG. 1 is a cross-sectional view illustrating a chip structure having an interconnect according to an embodiment of the present disclosure.

Hereinafter, a chip structure 1 having an interconnect according to an embodiment of the present disclosure will be described in detail with reference to the accompanying drawings. Referring to FIG. 1, the present disclosure relates to a chip structure 1 having an interconnect and, more particularly, to the chip structure 1 having an interconnect, in which a buffer layer is formed between an upper metal structure and a passivation layer under the upper metal structure so as to prevent fractures, such as cracks, from occurring in the passivation layer due to difference of stress between the upper metal structure and the passivation layer.

The term ‘chip’ above is understood as an IC chip, and the ‘interconnect’ is understood as a structure for electrically connecting metal wirings within the chip to devices such as external chips.

First, the chip structure 1 having an interconnect according to an embodiment of the present disclosure has a substrate 101. A transistor (not shown) may be formed on one surface of the substrate 101. In addition, an insulating film 103 may be formed on the substrate 101, and multiple layers of metal wirings M1, M2, and M3, etc. may be formed within the insulating film. In addition, each of the metal wirings M1, M2, and M3, etc. is composed of a single metal or an alloy film including different metals and, for example, preferably includes an aluminum Al film, but there is no separate limitation thereto.

In addition, each of the metal wirings M1, M2, and M3, etc. may be electrically connected to each other by a contact plug C. The contact plug C may be formed through a damascene process within the insulating film 103, and may be composed of a conductive ionic material, for example, any one of a polycrystalline silicon film doped with impurity ions, a metal, and an alloy film including different metals, to electrically connect the metal wirings M1, M2, and M3, etc., which are stacked.

In addition, the insulating film 103 may be formed as an oxide film selected from, for example, BPSG, PSG, BSG, USG, TEOS, and HDP films, or as a stacked film in which two or more layers of these are stacked. Furthermore, the insulating film 103 may be planarized for example, by a CMP process after the insulating film 103 is deposited.

In addition, a metal pad 105 may be formed on the insulating film 103 or in an upper portion of the insulating film 103. The metal pad 105 is composed of a single metal or an alloy film including different metals and, for example, preferably includes an aluminum Al film, but there is no separate limitation thereto.

In addition, a passivation layer 110 may be formed on the insulating film 103. The passivation layer 110 is formed, for example, to cover the metal pad on the insulating film 103, and may have one or more via holes 111. Each of the via holes 111 is formed in a shape vertically penetrating the passivation layer 110, and is preferably formed on the upper surface of the metal pad 105. Through the via hole 111, the upper surface of the metal pad 105 may have a side that is not covered by the passivation layer 110. The passivation layer 110 described above may include, for example, silicon oxide, silicon nitride, or silicon oxynitride, but is not particularly limited thereto.

Within the via hole 111 above, a barrier layer 120 may be formed along the inner wall of the via hole 111. The barrier layer 120 is a thin film formed on the inner side wall and lower surface of the via hole 111, and may include, for example, a Ti layer and/or TiN layer. The barrier layer 120 is intended to prevent interaction between a gap fill layer 130 to be described later and the metal pad 105. Between the adjacent via holes 111 immediately under an upper metal structure 160 to be described later, the barrier layer 120 may remain to have a predetermined thickness, or may be removed, and there is no separate limitation thereto.

In addition, the gap fill layer 130 may be formed on the barrier layer 120 within the via hole 111. The gap fill layer 130 preferably includes, for example, a W (tungsten) layer, and more preferably is made of the W layer. The gap fill layer 130 is preferably made of a material identical to a material of a buffer layer 140 to be described later.

In addition, the buffer layer 140 may be formed on the passivation layer 110 and the gap fill layer 130. The buffer layer 140 is intended to prevent cracks that may occur in the passivation layer 110 due to the formation of the upper metal structure 160 to be described later, and is preferably formed only on the lower side of the upper metal structure 160. In addition, the buffer layer 140 preferably includes a material identical to a material of the gap fill layer 130, and is more preferably made of the material identical to the material of the gap fill layer 130. In an embodiment, the buffer layer 140 may include a single layer made of W (tungsten). In an alternative embodiment, the buffer layer 140 may have a structure in which at least one layer of a Ti layer, a TiN layer, and a TiW layer is stacked on the W layer.

In addition, an under bump metal (UBM) layer 150 may be formed on the buffer layer 140. The UBM layer 150 is formed between the buffer layer 140 and the upper metal structure 160, and may include a first layer 151 and a second layer 153. The first layer 151 is formed between the buffer layer 140 and the second layer 153 and may, for example, be formed as a Ti or TiW layer. The first layer 151 may facilitate the easy adhesion of the upper metal structure 160.

In addition, the second layer 153 is formed on the first layer 151 and is preferably made of a metal identical to a metal of the lower portion of the upper metal structure 160 and, for example, may be made of Cu. The second layer 153 may be referred to as a seed Cu layer. That is, the second layer 153 is a layer for forming the upper metal structure 160, which will be described later, by electroplating. The second layer 153 preferably has a vertical thickness greater than or equal to the vertical thickness of the first layer 151.

In addition, the upper metal structure 160 may be formed on the UBM layer 150. The upper metal structure 160, which includes one or more metal layers, may, for example, include a first metal layer 161, which is a Cu metal layer, formed on a lower layer, a second metal layer 163, which is a Ni metal layer, formed on the first metal layer 161, and a third metal layer 165, which is an Au metal layer, formed on the second metal layer 163, but is not limited thereto. The upper metal structure 160 may be formed as a single Cu metal layer. In addition, the first metal layer 161 is preferably formed as the same metal layer as the second layer 153 described above, and is more preferably formed as a Cu metal layer, for example. The second metal layer 163 is a layer to prevent the diffusion of Cu of the first metal layer 161, and is preferably a Ni layer, for example. The third metal layer 165 is a layer for electrical connection with a structure to be formed on the third metal layer 165, and is preferably an Au layer, for example.

In addition, the first metal layer 161 may have a larger vertical thickness than each of the second metal layer 163 and the third metal layer 165. For example, the first metal layer 161 may have a vertical thickness of 10 μm, the second metal layer 163 may have a vertical thickness of 3 μm, and the third metal layer 165 may have a vertical thickness of 0.5 μm, but the scope of the present disclosure is not limited by the above figures.

Hereinafter, a manufacturing method of the chip structure having an interconnect according to an embodiment of the present disclosure will be described in detail with reference to the accompanying drawings. For convenience of description, only a process after forming the insulating film 103 and the metal pad 105 will be described in detail below.

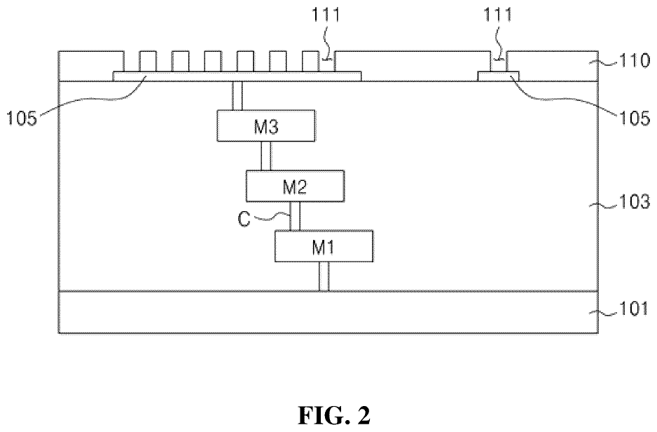

FIGS. 2 to 11 are cross-sectional views illustrating a manufacturing method of the chip structure having an interconnect according to an embodiment of the present disclosure.

Referring to FIG. 2, first, the passivation layer 110 is formed on the insulating film 103, and the via hole 111 is formed in the passivation layer 110. The via hole 111 may be formed through an etching process after forming a mask pattern on the passivation layer 110. The via hole 111 may have an inner surface extending vertically along a vertical direction or have a width gradually narrowing downward, and there is no separate limitation thereto. The upper surface of the metal pad 105 may have a side that is open to the outside due to the formed via hole 111. As described above, the via hole 111 may be formed as one via hole or may include multiple via holes formed to be spaced apart from each other, and there is no separate limitation thereto.

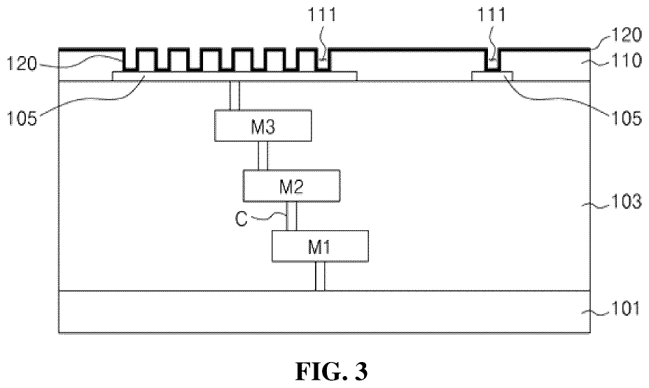

Next, referring to FIG. 3, the barrier layer 120 is formed on the passivation layer 110 and along the inner wall of the via hole 111. The barrier layer 120 may include, for example, a Ti layer and/or TiN layer. As described above, the barrier layer 120 is configured to prevent interaction between the gap fill layer 130 and the metal pad 105.

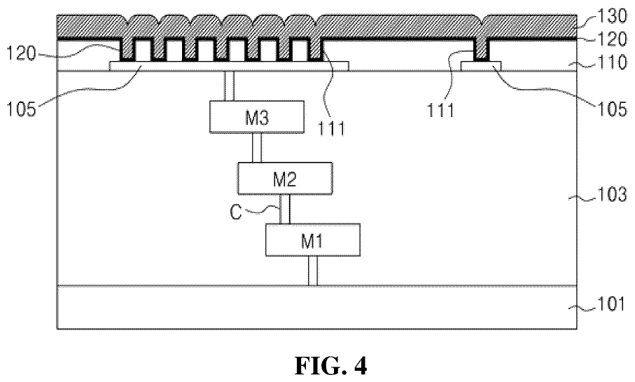

After forming the barrier layer 120, referring to FIG. 4, the gap fill layer 130 is formed inside the via hole 111. The gap fill layer 130 may be formed on the barrier layer 120 inside the via hole 111. In addition, the gap fill layer 130 may also be deposited on the barrier layer 120 outside the via hole 111. The gap fill layer 130 may be a W (tungsten) layer.

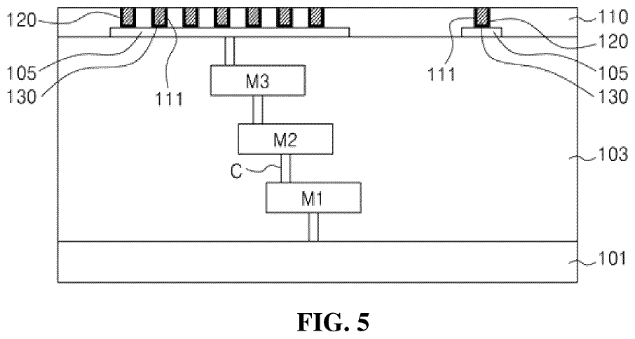

Next, referring to FIG. 5, in an embodiment, the gap fill layer 130 and the barrier layer 120 on the passivation layer 110 outside the via hole 111 are removed. This process may be performed through the CMP process.

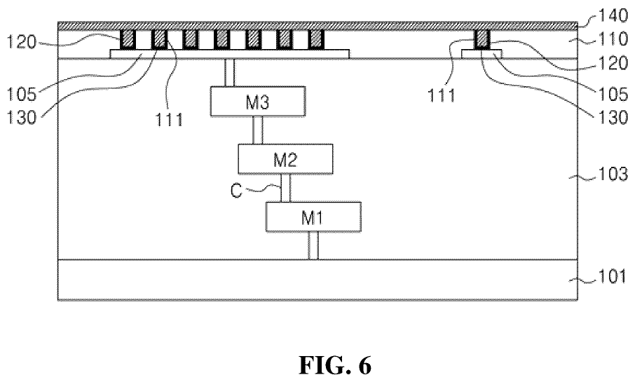

In an alternative embodiment, during the CMP process, the gap fill layer 130 outside the via hole 111 may not be completely removed but may remain to have a predetermined thickness (see FIG. 6). In this process, there is no need to perform a separate subsequent formation process of the buffer layer 140. In this case, the barrier layer 120 may remain to have a predetermined thickness on the passivation layer 110 between the adjacent via holes 111, or may be removed before the deposition of the gap fill layer 130, and there is no separate limitation thereto.

Returning to the embodiment again with reference to FIG. 6, the buffer layer 140 is formed on the gap fill layer 130.

For example, the buffer layer 140 may be formed by forming a W (tungsten) layer on the gap fill layer 130 and the passivation layer 110. For another example, a W layer may be formed on the gap fill layer 130 and the passivation layer 110, and at least one layer of a Ti layer, a TiN layer, and a TiW layer may be additionally formed on the W layer. It is preferable that the buffer layer 140 includes a material identical to a material of the gap fill layer 130, and it is more preferable that the buffer layer 140 is made of a material identical to a material of the gap fill layer 130.

As described above, the buffer layer 140 may serve as a protective layer to prevent the possibility of cracks occurring in the passivation layer 110 due to stress applied to the passivation layer 110 when the upper metal structure 160 is formed.

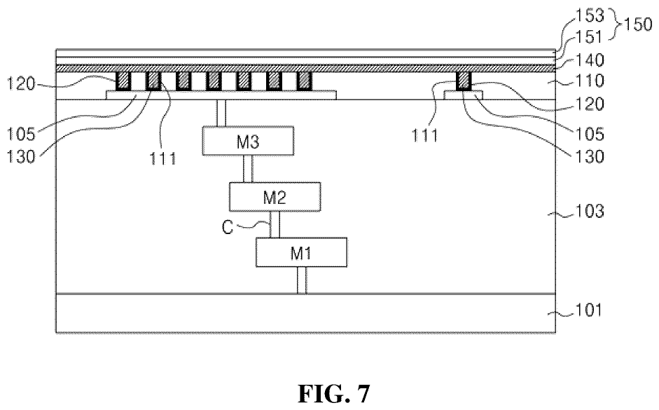

Referring to FIG. 7, after forming the buffer layer 140, the UBM layer 150 may be formed on the buffer layer 140. The UBM layer 150 may include, for example, the first layer 151 of Ti or TiW and the second layer 153, which is the seed Cu layer.

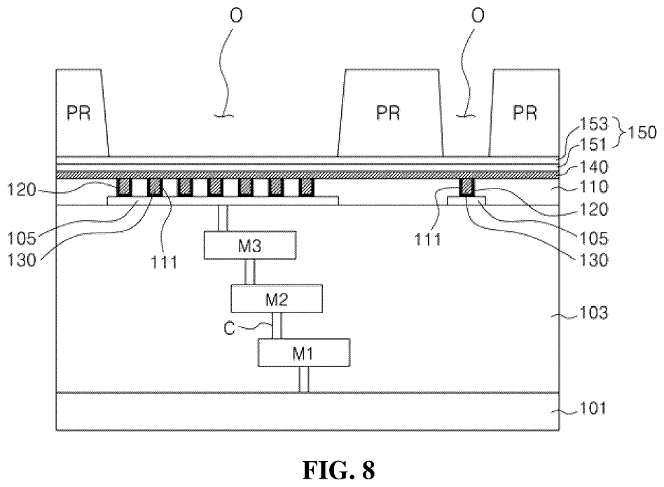

Referring to FIG. 8, when the UBM layer 150 is formed, the upper metal structure 160 is formed on the UBM layer 150. First, a photoresist film PR is formed on the UBM layer 150. In this case, the photoresist film PR may have an opening O at a side at which the upper metal structure 160 is formed.

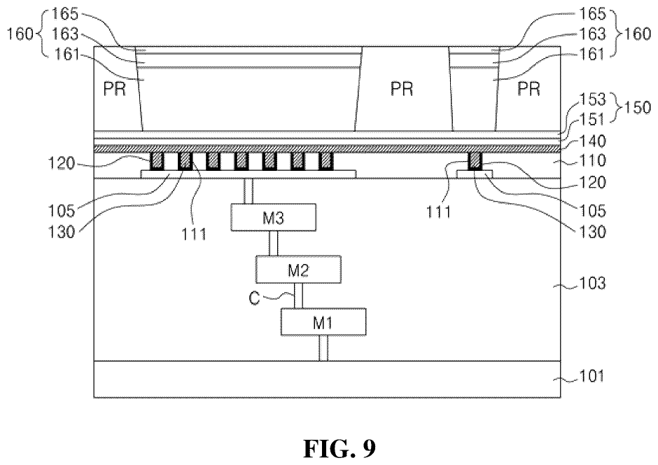

Referring to FIG. 9, next, the first metal layer 161, the second metal layer 163, and the third metal layer 165 may be sequentially formed within the opening O. As described above, the first metal layer 161 may be a Cu metal layer, the second metal layer 163 may be a Ni metal layer, and the third metal layer 165 may be an Au metal layer, but the scope of the present disclosure is not limited thereto.

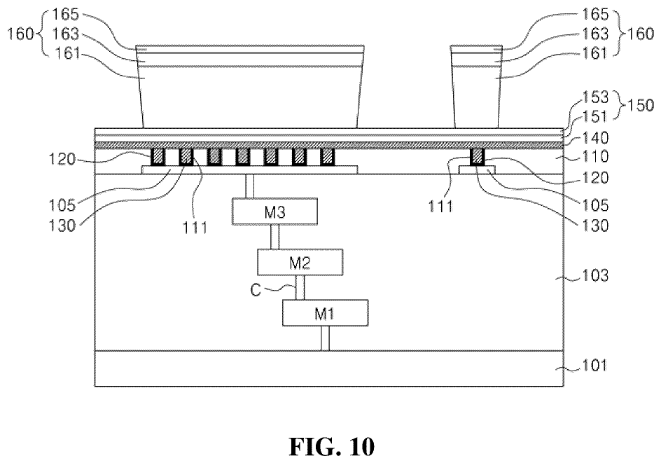

Referring to FIG. 10, next, the photoresist film PR on the UBM layer 150 may be removed by performing a stripping process.

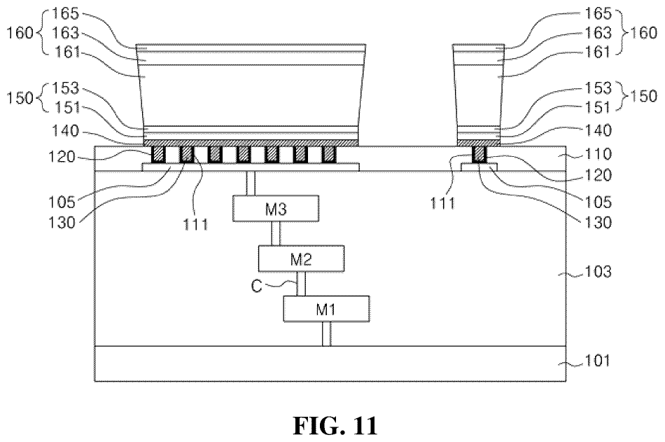

Finally, referring to FIG. 11, the UBM layer 150 and the buffer layer 140 at a side which is not covered by the upper metal structure 160 may be removed. This process may be performed through an etching process, and a wet etching process is preferably performed.

The detailed description above is illustrative of the present disclosure. Additionally, the foregoing describes preferred embodiments of the present disclosure, and the present disclosure may be used in various other combinations, modifications, and circumstances thereof. That is, changes or modifications may be made within the scope of the concept of the invention disclosed in this specification, a scope equivalent to the written disclosure, and/or the scope of technology or knowledge in the art. The above-described embodiments illustrate the best state for implementing the technical idea of the present disclosure, and various changes thereof required for specific application fields and uses of the present disclosure are also possible. Accordingly, the above detailed description of the invention is not intended to limit the present disclosure to the disclosed embodiments.

What is claimed is:

1. A chip structure having an interconnect, the chip structure comprising:
a substrate;
an insulating film disposed on the substrate;
multiple layers of metal wirings disposed within the insulating film;
a contact plug electrically connecting the multiple layers of metal wirings to each other;
a metal pad disposed on the insulating film or in an upper portion of the insulating film;
a passivation layer disposed on the insulating film and having one or more via holes;
a metal material layer configured to fill each of the one or more via holes;
a buffer layer disposed on the passivation layer and the metal material layer;
a UBM layer disposed on the buffer layer; and
an upper metal structure disposed on the UBM layer.

2. The chip structure of claim 1, wherein the metal material layer comprises:
a barrier layer disposed along an inner wall of each of the one or more via holes; and
a gap fill layer disposed inside each of the one or more via holes and on the barrier layer.

3. The chip structure of claim 2, wherein the barrier layer is a Ti layer and/or a TiN layer.

4. The chip structure of claim 2, wherein the gap fill layer is a W layer.

5. The chip structure of claim 2, wherein the buffer layer, which is a protective layer, has a metal material identical to a metal material of the gap fill layer.

6. The chip structure of claim 5, wherein the buffer layer is a W layer.

7. The chip structure of claim 5, wherein the buffer layer has a structure in which a W layer and at least one layer of a Ti layer, a TiN layer, and a TiW layer on the W layer are stacked.

8. The chip structure of claim 5, wherein the UBM layer comprises:
a first layer disposed on the protective layer; and
a second layer disposed on the first layer.

9. The chip structure of claim 8, wherein the second layer has a metal material identical to a metal material of a lower portion of the upper metal structure.

10. The chip structure of claim 9, wherein the second layer is a Cu metal layer.

11. The chip structure of claim 10, wherein the upper metal structure comprises:
a first metal layer disposed on a lowest side of the upper metal structure;
a second metal layer disposed on the first metal layer; and
a third metal layer disposed on the second metal layer,
wherein each of the first metal layer, the second metal layer, and the third metal layer has a metal material different from a metal material of another.

12. The chip structure of claim 11, wherein the first metal layer has a larger vertical thickness than a vertical thickness of each of the second metal layer and the third metal layer.

13. A chip structure having an interconnect, the chip structure comprising:
a substrate;
an insulating film disposed on the substrate;
a metal pad disposed on the insulating film or in an upper portion of the insulating film;
a passivation layer having a via hole and disposed on the insulating film;
a barrier layer extending along an inner wall of the via hole;
a gap fill layer disposed inside the via hole and on the barrier layer;
a buffer layer disposed on the passivation layer and the gap fill layer;
a UBM layer, which is a multilayer film structure, disposed on the buffer layer; and
an upper metal structure disposed on the UBM layer,
wherein the gap fill layer has a metal material identical to a metal material of the buffer layer.

14. The chip structure of claim 13, wherein the UBM layer comprises:
a first layer; and
a second layer disposed on the first layer,
wherein the second layer has a metal material identical to a metal material of a lower portion of the upper metal structure in contact with an upper surface of the second layer.

15. The chip structure of claim 13, wherein the buffer layer is formed together with the gap fill layer during a CMP process to complete the gap fill layer.

16. A method of manufacturing a chip structure having an interconnect, the method comprising:
forming a passivation layer on an insulating film in which a metal wiring layer is formed;
forming one or more via holes inside the passivation layer;
forming a barrier layer along an inner wall of each of the one or more via holes;
forming a gap fill layer on the barrier layer within each of the one or more via holes;
forming a buffer layer on the gap fill layer;
forming a UBM layer on the buffer layer; and
forming an upper metal structure on the UBM layer.

17. The method of claim 16, wherein the barrier layer and the gap fill layer are formed by forming the barrier layer along the inner wall of each of the one or more via holes, forming the gap fill layer on the barrier layer, and then removing at least a portion of the gap fill layer remaining outside each of the one or more via holes through a CMP process.

18. The method of claim 17, wherein the buffer layer is formed by removing a predetermined thickness of the gap fill layer remaining outside each of the one or more via holes through the CMP process.

19. The method of claim 16, wherein the forming of the UBM layer comprises:
forming a first layer comprising a Ti layer or a TiW layer; and
forming a second layer, which is a Cu layer, on the first layer.

20. The method of claim 16, wherein the forming of the upper metal structure comprises:
forming a photoresist film on the UBM layer, the photoresist film having an opening; and
forming a plurality of metal layers sequentially within the opening.
